(19) United States
(12) Patent Application Publication
(10) Pub. No.: US 2013/0064992 A1
(43) Pub. Date: Mar. 14, 2013

(54) Process for Eliminating Fog Particles on a Surface of High P Concentration PSG Film

(71) Applicants: Meimei GU, Shanghai (CN); Ke WANG, Shanghai (CN); Chienwei CHEN, Shanghai (CN); Hsusheng CHANG, Shanghai (CN)

(72) Inventors: Meimei GU, Shanghai (CN); Ke WANG, Shanghai (CN); Chienwei CHEN, Shanghai (CN); Hsusheng CHANG, Shanghai (CN)

(73) Assignee: SHANGHAI HUALI MICROELECTRONICS CORPORATION, Shanghai (CN)

(21) Appl. No.: 13/339,581

(22) Filed: Dec. 29, 2011

(30) Foreign Application Priority Data
Sep. 8, 2011 (CN) 201110265302.8

(51) Int. Cl. C23C 16/22

(52) U.S. Cl. 427/569

(57) ABSTRACT

A process for eliminating fog particles on a surface of a high P concentration PSG film is provided. The process mainly comprises steps of: feeding oxygen to a plasma environment in a reaction chamber; mixing plasma with oxygen; causing oxygen to react with unstable phosphorus atoms in the PSG film by using energy of plasma; and forming a passive film on the surface of the PSG film to prevent phosphorus in the PSG film from reacting with hydrogen and oxygen in the air. With the process for eliminating fog particles on a surface of a high P concentration PSG film, by feeding oxygen into the reaction chamber, the high-density plasma can be mixed with oxygen effectively, so as to achieve formation of the passive film on the surface of the phosphosilicate glass and thereby block water vapour from contacting boron and phosphorus to cause crystallization.

### CROSS REFERENCE TO RELATED APPLICATIONS

The present application is based upon and claims priority under 35 U.S.C. §119 to prior Chinese Patent Application No. 201110265302.8 filed on Sep. 8, 2011, the entire contents of which are incorporated herein by reference.

### TECHNICAL FIELD

The invention relates to a process, and more particularly, to a process for eliminating fog particles (nepheloid particles) on a surface of a high P concentration PSG (phosphosilicate glass) film.

### BACKGROUND

Generally, a high P concentration PSG is grown by using a high-density plasma chemical vapor deposition (HDP CVD), and fog particles are formed on a processed surface of the high P concentration PSG. These fog particles are formed because phosphorus, after absorbed water, crystallizes on the surface, and thus results in a rough surface of the film. It is shown that there are a large number of such particles with tiny sizes (0.09 to 0.1 μm) under an inspection, and such particle inspection can remarkably affect estimation of actual particles and thus misguide a result of the process monitor. At present, in order to prevent the fog particles from occurring, a layer of silicon oxide is often selected to cover the high P concentration PSG, so as to obstruct corrosion of water vapor in the air and crystallization resulted from water vapor contacting boron and phosphorus. Such solution, however, normally can only treat a phosphosilicate glass containing 4 percent boron and phosphorus. If a phosphosilicate glass having a high P concentration is covered by a silicon oxide layer too, then in view of a process integration, the control of the subsequent Chemical Mechanical Polishing (CMP) will be disadvantageously influenced, because a polishing rate of the CMP is linearly related to a percentage of phosphorus content, as shown in FIG. 1, that is, the higher the percentage of phosphorus content is, the higher the polishing rate of CMP (including a etching rate) is, and the higher the polishing rate ratio of the CMP to phosphosilicate glass (PSG) and silicon oxide could thus be. Accordingly, in processing phosphosilicate glass of an actual high phosphorus content, if a covering layer of silicon oxide is added, once this layer of silicon oxide is polished away through CMP, polishing can hardly be properly stopped but be accelerated to polish the subjacent phosphosilicate glass 4, which will eventually cause a thickness of the phosphosilicate glass film uncontrollable.

### SUMMARY OF THE INVENTION

The invention discloses a process for eliminating fog particles on a surface of a high P concentration PSG film. The process method can solve the problem of fog-like particles in the prior art, that is, in processing phosphosilicate glass having a relatively high phosphorus content, phosphorus in the PSG film reacts with hydrogen and oxygen in the air and subsequently gets damp by absorbing water, thereby phosphorus crystallization is in turn formed to produce fog particles.

In order to achieve the above object, the invention adopts the following technical solutions.

A process for eliminating fog particles on a surface of a high P concentration PSG film comprises:
feeding oxygen to a plasma environment in a reaction chamber; mixing plasma with oxygen; causing oxygen to react with unstable phosphorus atoms in the PSG film by using energy of plasma; and forming a passive film on the surface of the PSG film to prevent phosphorus in the PSG film from reacting with hydrogen and oxygen in the air.

According to the process, in the process of feeding oxygen to the reaction chamber, a flow rate of oxygen fed via gas vent(s) in a top of the reaction chamber may be set to 350 sccm, and a flow rate of oxygen fed via gas vent(s) in a side wall of the reaction chamber may be set to 150 sccm, so as to ensure a uniform distribution of oxygen in the reaction chamber.

According to the process, the high P concentration PSG (P-doped silica glass) may be produced by a high density plasma chemical vapor deposition process, and a concentration of doped phosphorus is no lower than 9%.

According to the process method, in the process of generating plasma in the reaction chamber, a radio-frequency (RF) power distributed to a top of the reaction chamber may be set to 2500 W, a radio-frequency power distributed to a side wall of the reaction chamber may be set to 1000 W, and a radio-frequency power distributed to a bottom of the reaction chamber may be set to 5500 W, so as to ensure a uniform distribution of plasma in the reaction chamber.

According to the process of the invention for eliminating fog particles on a surface of a high P concentration PSG film, the following solution is adopted and the following effects are achieved: feeding oxygen to a reaction chamber so that oxygen reacts with unstable phosphorus atoms in the PSG film, and thus forming a passive film on the surface of the PSG film to give stability to phosphorus with unstable chemical properties in the phosphosilicate glass, such that phosphorus in the PSG film can be prevented from reacting with hydrogen and oxygen in the air and subsequently getting damp by absorbing water to cause phosphorus crystallization, and thusly the problem of fog particles can be avoided.

### BRIEF DESCRIPTION OF THE DRAWINGS

Other features, objects and advantages of the invention will become more obvious from the following description of the unrestrictive embodiments of the invention with reference to the appended drawings, in which:

FIG. 1 is a graph showing a linear relation of a polishing rate of CMP and a P concentration (concentration of phosphorus) in a process method for eliminating fog particles on a surface of a high P concentration PSG film according to the invention; and

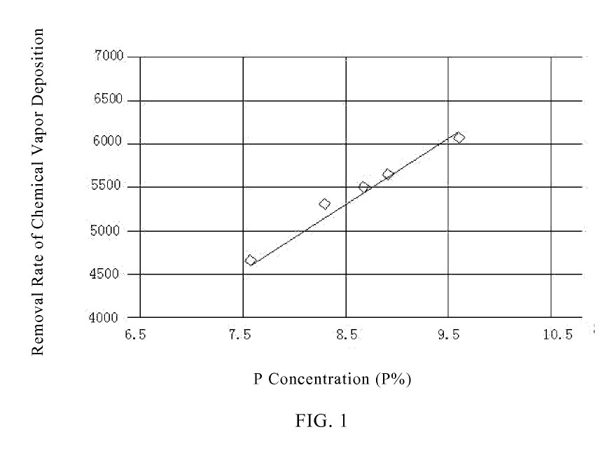

FIG. 2 is a schematic diagram illustrating the process method for eliminating fog particles on a surface of a high P concentration PSG film according to the invention.

### LIST OF THE REFERENCE NUMERALS

“1” is used to indicate a reaction chamber;
“2” is used to indicate a PSG film;
“3” is used to indicate a passive film;
“4” is used to indicate a gas vent;
“5” is used to indicate a radio-frequency generator.

### DETAILED DESCRIPTION OF THE EMBODIMENTS

In order to understand the technical means for implementing the invention, the inventive features, the objects to be achieved, and the effects to be appreciated, the invention will be described in detail hereinafter with reference to the drawings.

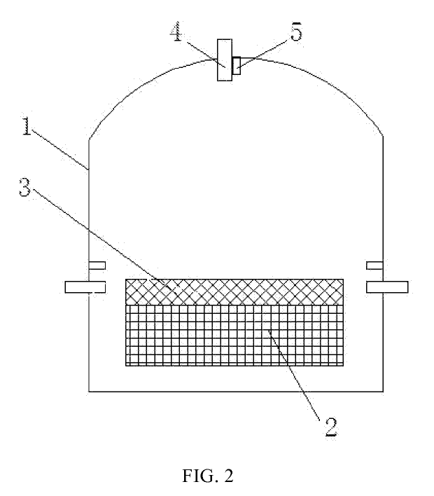

Referring to FIG. 2, the invention provides a process method for eliminating fog particles on a surface of a high P concentration PSG film, comprising the steps of: feeding oxygen to a plasma environment in a reaction chamber 1, wherein oxygen is fed via gas vents 4 provided in a top and a side wall of the reaction chamber 1, respectively; mixing plasma with oxygen; causing oxygen to react with unstable phosphorus atoms in the PSG film 2 by using energy of plasma; forming a passive film 3 on a surface of the PSG film 2 to prevent phosphorus in the PSG film 2 from reacting with hydrogen and oxygen in the air.

Furthermore, in the process of feeding oxygen to the reaction chamber 1, a flow rate of oxygen fed via the gas vent 4 in the top of the reaction chamber 1 may be set to 350 sccm, and a flow rate of oxygen fed via the gas vent 4 in the side wall of the reaction chamber 1 may be set to 150 sccm. Oxygen is fed via the gas vent 4 in the top and the gas vent 4 in side wall of the reaction chamber 1 at the same time, respectively, so as to ensure a uniform distribution of oxygen in the reaction chamber 1, and to ensure the distributed oxygen being able to sufficiently react with the unstable phosphorus atoms in the PSG film 2.

Furthermore, the P-doped silica glass may be produced by a high-density plasma chemical vapor deposition process, and a concentration of the doped phosphorus may be no lower than 9%. When the P concentration is higher than 9%, the doped phosphorus atoms in the phosphosilicate glass can effectively react with oxygen to form a passive film 3 on the surface of the PSG film 2.

Furthermore, in the process of generating plasma in the reaction chamber 1, the radio-frequency (RF) power distributed to the top of the reaction chamber 1 may be set to 2500 W, the radio-frequency power distributed to the side wall of the reaction chamber 1 may be set to 1000 W, and the radio-frequency power distributed to a bottom of the reaction chamber 1 may be set to 5500 W, thereby radio-frequency energy emitted by radio-frequency generators 5 provided on the top and the side wall of the reaction chamber 1 may ensure a uniform distribution of plasma inside the reaction chamber 1.

Meanwhile, by using energy of plasma, oxygen may react with unstable bonds of phosphorus in the phosphosilicate glass, for example, oxygen may combine with dangling bonds (P⁻) of phosphorus, so as to make phosphorus with unstable chemical properties in the phosphosilicate glass be stable. The formed passive film 5 can prevent phosphorus from reacting with hydrogen and oxygen in the air, so as to solve the problem of fog particles caused by phosphorus crystallization which is in turn resulted from that the high P concentration phosphosilicate glass, after deposited in the air, becomes damp due to absorbing water. Furthermore, high-density plasma and oxygen are mixed inside the reaction chamber 1.

In sum, the invention provides a process method for eliminating fog particles on a surface of a high P concentration PSG film comprising: feeding oxygen to a reaction chamber; effectively mixing high-density plasma with oxygen, so as to achieve formation of a passive film on a surface of the PSG film and thereby block water vapour from contacting boron and phosphorus etc. to form crystallization.

Although some specific embodiments of the invention have been described above, it should be appreciated that the invention does not intend to be limited to the above specific embodiments, and equipments and structures that are not described in detail may be implemented in the common ways in the art. Various of variations and modifications can be made within the scope of the claims by the person skilled in the art without affecting the substance of the invention.

1. A process for eliminating fog particles on a surface of a high P concentration PSG film, mainly comprising steps of:
feeding oxygen to a plasma environment in a reaction chamber; mixing plasma with oxygen; causing oxygen to react with unstable phosphorus atoms in the PSG film by using energy of plasma; and forming a passive film on the surface of the PSG film to prevent phosphorus in the PSG film from reacting with hydrogen and oxygen in the air.

2. The process in accordance with claim 1, wherein in the process of feeding oxygen to the reaction chamber, a flow rate of oxygen fed via a gas vent in a top of the reaction chamber is 350 sccm, and a flow rate of oxygen fed via a gas vent in a side wall of the reaction chamber is 150 sccm, for ensuring a uniform distribution of oxygen in the reaction chamber.

3. The process in accordance with claim 1, wherein the high P concentration PSG film is produced by a high density plasma chemical vapor deposition process, and a concentration of doped phosphorus is no lower than 9%.

4. The process in accordance with claim 1, wherein in the process of generating plasma in the reaction chamber, a radio-frequency power distributed to a top of the reaction chamber is 2500 W, a radio-frequency power distributed to a side wall of the reaction chamber is 1000 W, and a radio-frequency power distributed to a bottom of the reaction chamber is 5500 W, for ensuring a uniform distribution of plasma in the reaction chamber.
